(19) United States
(12) Patent Application Publication
(10) Pub. No.: US 2006/0092695 A1
(43) Pub. Date: May 4, 2006

(54) Hybrid memory array with single cycle access

(76) Inventors: Malcolm J. Wing, Palo Alto, CA (US); Godfrey Paul D'Souza, San Jose, CA (US); Ed McKernan, Los Altos, CA (US)

Correspondence Address: Stephen L. King, 4642 Oyster Bay Road NW, Olympia, WA, 98502, US

(21) Appl. No.: 10/979,839

(22) Filed: Nov. 2, 2004

(51) Int. Cl. G11C 11/50; G11C 11/00

(52) U.S. Cl. 365/164; 365/153

(57) ABSTRACT

A memory array including a hybrid electromechanical and semiconductor memory cell, and circuitry for addressing and controlling read, write, and erase accesses of the memory cells to be of a single cycle.

### BACKGROUND OF THE INVENTION

1. Field of the Invention

This invention relates to hybrid electromechanical and semiconductor memory arrays and, in particular, to hybrid electromechanical and semiconductor memory arrays providing single cycle read and write accesses.

2. History of the Prior Art

Memory structures are an essential building block for electronics devices and systems. Important characteristics of these structures are data retention, density, cost, power, and speed. There are a number of different types of memory structures which display differing characteristics making them suitable for different applications.

For example, read only memory (ROM) is relatively low cost but cannot be written. Programmable read only memory (PROM), electrically programmable read only memory (EPROM), and electrically erasable programmable read only memory (EEPROM) have read cycles that are fast relative to ROM and can be written; however, each has relatively long erase times and can be written reliably only over a only few iterative read/write cycles. Dynamic random access memory (DRAM) may be written and read rapidly but stores charge on capacitors which must be electrically refreshed by separate circuitry every few milliseconds to retain the memory contents. Static random access memory (SRAM) does not need to be refreshed and is fast relative to DRAM but is also more expensive. Both SRAM and DRAM are volatile in the sense that they do not retain stored data when power to the computer is removed.

Recently, the authors of “Carbon Nanotube-Based Nonvolatile Random Access Memory for Molecular Computing,” Science, vol. 289, pp. 94-97, Jul. 7, 2000, proposed memory devices which use nanoscopic wires, such as single-walled carbon nanotubes, to form crossbar junctions to serve as memory cells. The article describes individual single-walled nanotube wires suspended over other wires to define memory cells. Electrical signals are written to one or both wires to generate electrostatic fields which cause the wires to physically attract one another. Wires which have not been attracted form an open circuit junction, while attracted wires touch and form a rectified junction. Each physical state (i.e., attracted or open) corresponds to an electrical state. When electric power is removed from the junction, the wires retain their physical (and thus electrical) state thereby forming a non-volatile memory cell. The carbon nanotube memory cell device described in the article is referred to hereinafter as an electromechanical device or MEMS.

U.S. Pat. No. 6,574,130, entitled “Hybrid Circuit Having Nanotube Electromechanical Memory,” Segal et al, furnishes additional details including modifications for manufacturability of such memory devices including various forms of the nanoscopic elements themselves such as web-like meshes.

As the patent discloses, it is possible to construct a hybrid semiconductor and electromechanical technology memory cell as part of a memory array device with circuit connections to address decode logic, input/output data logic, and control logic to enable read, write/erase accesses. Typically these accesses are synchronized to a periodic signal (clock). Various connection schemes and associated signaling are possible with these hybrid technology memory cells and arrays. Such hybrid memory cells and arrays may be used to form the more complicated circuits and systems (e.g., field programmable memory arrays) which find use in advanced electronic systems such as computers.

Even though these new nanotube devices provide dense, non-volatile memory structures which may be written and read relatively rapidly, it is desirable to enhance the operations of nanotube memory structures. It is especially desirable to provide hybrid memory cell arrays embodying a connection and signaling scheme to allow single cycle accesses for both read and write operations.

### SUMMARY OF THE INVENTION

The present invention is realized by a memory array including a hybrid electromechanical and semiconductor memory cell, and circuitry for addressing and controlling read, write, and erase accesses of the memory cells to be of a single cycle.

These and other objects and features of the invention will be better understood by reference to the detailed description which follows taken together with the drawings in which like elements are referred to by like designations throughout the several views. It is to be understood that, in some instances, various aspects of the invention may be shown exaggerated or enlarged to facilitate an understanding of the invention, and in other instances, some aspects of the invention considered to be conventional may not be shown so as to avoid obfuscating more important aspects or features of the invention.

### BRIEF DESCRIPTION OF THE DRAWINGS

FIG. 1 is a schematic diagram illustrating the internal memory cell structure of a prior art semiconductor technology SRAM memory device; FIG. 2 is a block diagram illustrating an embodiment of a prior art semiconductor technology SRAM memory array;

FIG. 3A is a diagram illustrating an embodiment of an electromechanical device which may be utilized in the present invention in a first switch-open condition;

FIG. 3B is a diagram illustrating an embodiment of an electromechanical device which may be utilized in the present invention in a first switch-closed condition;

FIG. 4 is a schematic diagram illustrating the embodiments of an electromechanical device illustrated in FIGS. 3A and 3B;

FIG. 5 illustrates an embodiment of a hybrid technology memory cells and memory array in accordance with the present invention;

FIG. 6 illustrates signal transitions of the single cycle read or write access of the hybrid technology memory array embodiment of FIG. 5.

### DETAILED DESCRIPTION

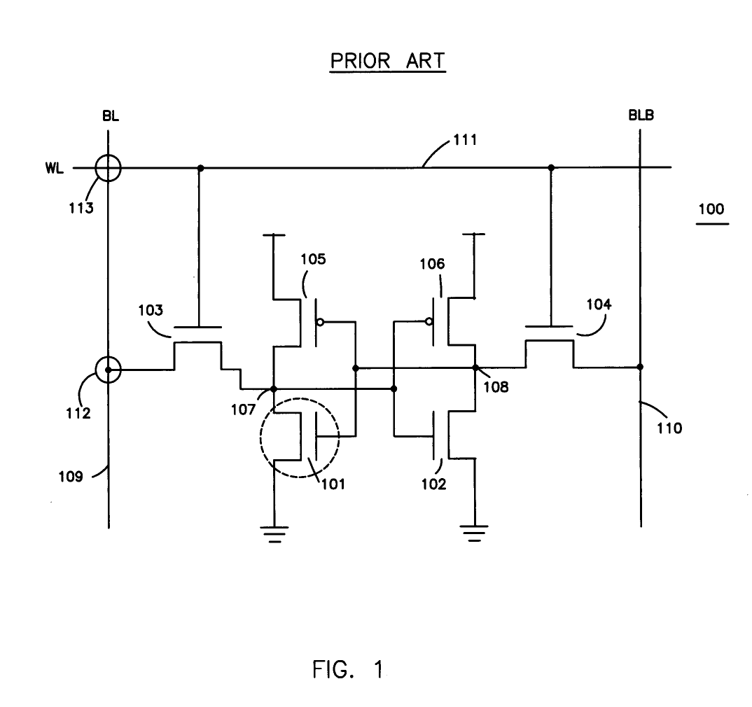

FIG. 1 is a schematic diagram of a prior art SRAM memory cell 100 which utilizes semiconductor technology and is useful in enabling one skilled in the art to practice the present invention. In the figure, a crossing such as that at a node 113 (circled for emphasis) indicates that there is no electrical connection between two conductors 111 and 109, whereas the dot at the crossing at a node 112 (circled for emphasis) indicates an electrical connection between the conductor 109 and a device 103.

The cell 100 includes both storage circuitry and access circuitry. N type metal oxide semiconductor (NMOS) device 101 and P type metal oxide semiconductor (PMOS) device 105 are connected together and to supply terminals as a first inverter gate device. Specifically, the gate terminals of the two metal oxide semiconductor (MOS-NMOS/PMOS) devices are tied together (node 108), and the drain terminals are tied together (node 107). The source terminal of the PMOS device 105 is connected to a positive supply, and the source terminal of the NMOS device 101 is connected to a negative supply (ground in this case). The shared gate node 108 may be viewed as the input node of the first inverter, and the shared drain node 107 may be viewed as the output node of the first inverter. Similarly, NMOS device 102 and PMOS device 106 are connected to form a second inverter gate device receiving input at node 107 and furnishing output at node 108.

The input of the first inverter is connected to the output of the second inverter, and the output of the first inverter is connected to the input of the second inverter, thus forming a feedback latch structure. This latch structure provides the storage circuitry component of the memory cell 100.

Access to the storage circuitry component of the memory cell 100 is provided by a pair of NMOS devices 103 and 104 and associated conductors. The NMOS device 103 connects the output node 107 of the first inverter (and the input of the second inverter) to a first bit line 109 (BL) and to a word line 111 (WL). More specifically, the source and drain terminals of device 103 connect bit line 109 to the output of the first inverter; and the gate terminal of device 103 connects to word line 111. Similarly, a NMOS device 104 is connected to the output of the second inverter 108 (also the input of the first inverter), a second bit line 110 (BLB), and the word line 111.

The SRAM storage circuitry is capable of storing a value until a new value is presented but loses any stored value if power is removed. To illustrate, a high or positive value of the power supply on a node may be referred to as a logic level of “ONE,” and a low or negative value of the power supply on a node may be referred to as a logic level “ZERO.” If a logic level ONE is presented to the node 107 while a logic level ZERO is presented simultaneously to the node 108, and then those levels are removed, the storage cell 100 assumes a condition which may be considered to represent a logic state of ONE. Since the input of the first inverter is at logic level ZERO, the device 105 is enabled driving its output to logic level ONE; similarly, the second inverter drives its output to logic level ZERO. Therefore, even after initial logic levels presented to the storage circuitry are removed, the storage circuitry stores (or maintains) the logic state ONE. If, on the other hand, a logic level ZERO is presented to the node 107 and a logic level ONE is simultaneously presented to the node 108 and these levels are subsequently removed, the storage cell maintains a logic state ZERO.

The access circuitry allow the storage circuitry to be written or read. Writing the storage cell occurs when bit lines 109 and 110 are presented with opposite logic levels and the word line node 111 is presented with a logic level ONE. As described, to write a logic state of ONE into the storage circuitry, the bit line 109 is presented with a logic level ONE, the bit line 110 is presented with a logic level ZERO, while the word line 111 is presented with a logic level ONE. One the other hand, to write a logic state of ZERO into the storage circuitry, opposite values are presented on bit line 109 and bit line 110 while the word line 111 is furnished a logic value ONE.

In order to read the state of the cell 100, the bit lines 109 and 110 are both actively driven to logic level ONE and subsequently held weakly or let float at that logic level while word line 111 receives a logic level ONE. If the storage circuitry has a logic state of ONE, the bit line 109 remains at a logic level of ONE and the bit line 110 is driven down towards logic level ZERO through NMOS devices 104 and 102. However, if the storage circuitry has a logic state of ZERO, the bit line 109 is driven towards logic level ZERO through NMOS devices 103 and 101 while the bit line 110 remains at logic level ONE. Since the capacitance and associated charge on bit lines 109 and 110 are typically large while the NMOS and PMOS device sizes are typically made as small as possible, it may take a relatively long time for the particular bit line being driven to reach logic level ZERO. In order to improve the speed of the read operation, special circuitry (such as sense amplifier circuitry) may be employed as part of the output data control circuitry to detect small differences between the bit line voltages instead of the full voltages that typically represent logic levels ZERO or ONE.

The memory cell 100 represents an example of a prior art arrangement providing single cycle access to a memory cell.

FIG. 2 is a block diagram illustrating a SRAM memory array block 200. The exemplary array 200 illustrated is a four cell structure 201. Each of the cells CELL11, CELL12, CELL21, CELL22 is a SRAM memory cell such as cell 100 shown in FIG. 1. Input addresses for read and write operations are split into X and Y addresses. The X decoder and buffers 202 receive the X address and clock (CLK) and provide output on shared word lines 204 (WL1) and 205( WL2). The word line 204 selects CELL11 and CELL21, while the word line 204 selects CELL12 and CELL22. The Y decoder and input/output buffer 203 receives as input the Y address, input data, access control signals (read/write/control), and clock (CLK). The block 203 furnishes output to the shared bit lines 206 (BL1), 207 (BLB1), 208 (BL2), and 209 (BLB2). The bit lines 206 and 207 are shared by CELL11 and CELL12, while the bit lines 208 and 209 are shared by CELL21 and CELL22. Memory cell accesses are accomplished as described earlier (in the description of FIG. 1) by selectively manipulating the word lines and the bit lines connecting to the desired memory cell.

The new type of memory storage device circuit disclosed in U.S. Pat. No. 6,574,130 can be used to construct a memory array that can be randomly accessed like an SRAM memory array yet is also nonvolatile or maintains state through power cycling.

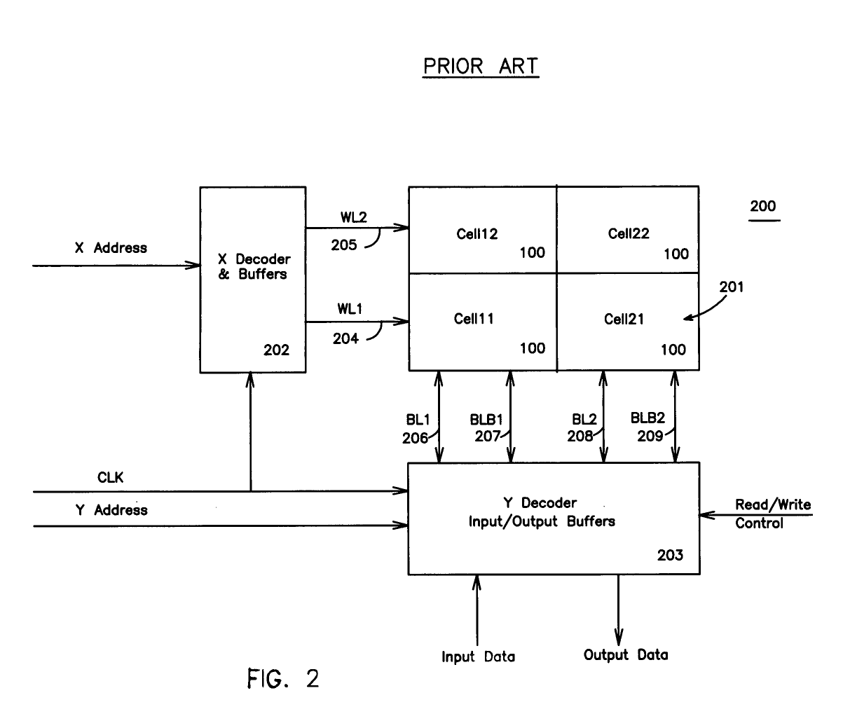

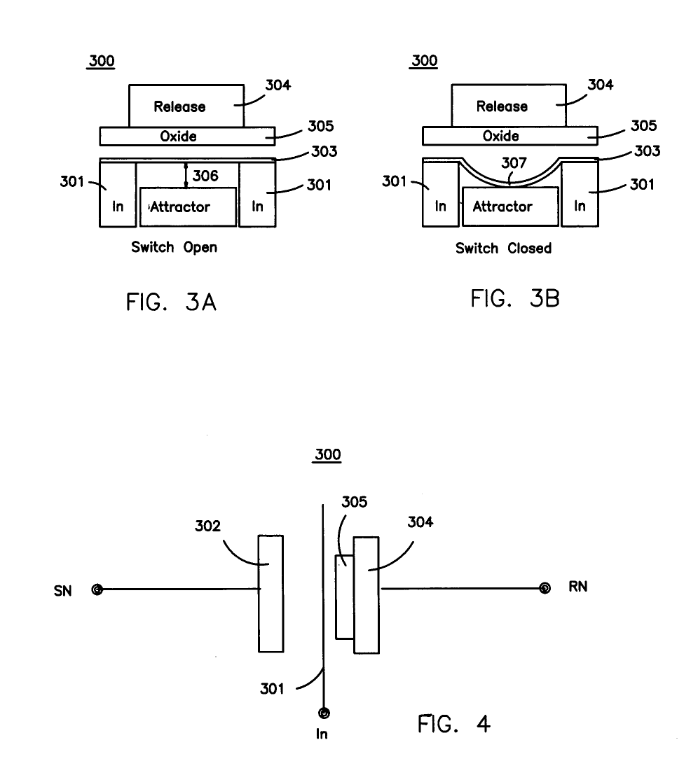

FIGS. 3A and 3B illustrate two physical cross sections of a carbon nanotube based electromechanical memory storage device or switch 300. FIG. 4 is a circuit schematic representing the same device 300. In the cross section illustrated in FIG. 3A, a carbon nanotube based layer 303 is suspended between two conductive posts 301. The posts 301 make electrical contact with the layer 303 at all times. Below the suspended layer 303 is an attractor plate 302. Above the layer 303 is a rigid oxide spacer 305, and above the spacer 305 is a release plate 304. In FIG. 3A, a gap 306 exists between the layer 303 and the attractor plate 302 so that there is no electrical contact therebetween. In this condition, the storage device (switch) 300 is considered open, a state which may be said to represent a logic state ONE. However, when the layer 303 is touching the attractor plate 302 without a gap and thus is making electrical contact as shown in FIG. 3B (position 307), the storage switch 300 is considered closed; and this state may be said to represent a logic state ZERO

In order to close the device 300, a potential difference or voltage is applied between the terminal 301 and a terminal to the attractor plate 302 and thus between the suspended layer 303 and the plate 302. The applied voltage is sufficiently high that field lines generated attract the suspended layer 303 towards the attractor plate 302 and the two eventually make electrical contact. Even after the voltage and corresponding field cease to exist, the layer 303 continues indefinitely to make contact with the attractor plate 302 due to atomic attraction forces (Van der Waals forces) and thus may be utilized to represent in a nonvolatile fashion the memory state of ZERO.

In order to open the switch 300 and produce a memory state of ONE, a potential difference or voltage is applied between the layer 303 and the release plate 304. The applied voltage is sufficiently high to generate field lines that attract the layer 303 back toward the release plate 304 to the suspended position illustrated in FIG. 3A. Even after the voltage and corresponding field cease to exist, the layer 303 continues to remain suspended indefinitely (with a gap 306) between the release plate 304 and the attractor plate 302. This state thus may represent a logic state ONE in a nonvolatile fashion.

The switch circuit schematic illustrated in FIG. 4 is a conceptual representation of the device 300 shown in FIGS. 3A and 3B and is not intended to communicate the switch open or closed states. The schematic is provided in order to facilitate the description of the following description of circuitry utilizing the device 300. It should be noted for such description that the attractor plate 302 is labeled SN, the release plate 304 is labeled RN, and the input terminal 301 is labeled IN.

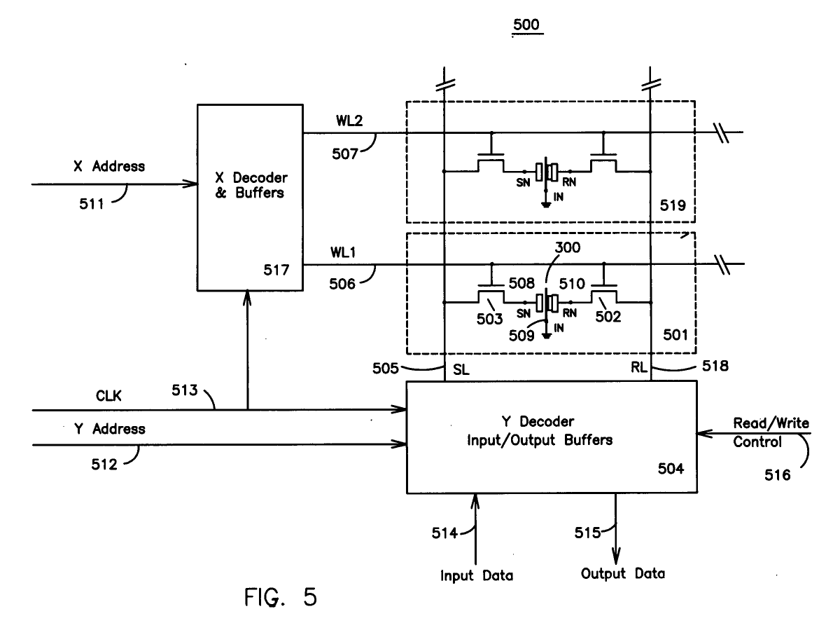

FIG. 5 is a partially-schematic, partially-block diagram of an exemplary array 500 in accordance with the present invention. The array 500 includes X and Y address buses 511 and 512, respectively, periodic (clock) signal lines 513, input data lines 514, output data lines 515, read/write control lines 516, X address decoder and buffers 517, Y address decoder input/output data buffers 504, and at least one hybrid electromechanical and semiconductor technology memory cell.

In this embodiment of the present invention, the X address decoder and buffers 517 receive input on the X address bus 511 and the clock signal lines 513 and furnish output on a first word line 506 (WL1) and a second word line 507 (WL2) to a first memory cell 501 and a second memory cell 519 for the purpose of accessing the memory cells during read or write operations. Although not shown here in order to maintain clarity, the X address decoder and buffers 517 may furnish additional signals (and include the necessary circuitry for accomplishing that purpose) not pertinent to the present invention but employed by those skilled in the art.

The Y address decoder and input/output data buffers 504 receive address signals on the Y address bus 512, clock signals on the clock signal lines 513, write data for a write operation on the input data lines 514, and read/write control signals on the read/write control lines 516. The Y address decoder 504 furnishes outputs on the column signal lines 505 (SL) and 518 (RL) to the first and second memory cells 501 and 519 for accessing the memory cells. The Y address decoder and input/output data buffers 504 furnishes output data on the lines 515 received as a result of a read operation on the lines 505 and 518. Although not shown here in order to maintain clarity, the Y address decoder 504 may input additional signals (and include the necessary circuitry for accomplishing that purpose) not pertinent to the present invention but employed by those skilled in the art.

The address signals on the X and Y address buses 511 and 512 when decoded uniquely identify at least one memory cell, for example, memory cell 501. The X address decoder 517 uses the decoded signals to present an appropriate voltage level on the first word line 506 to select memory cell 501 while holding the voltage level on the second word line 507 at an inactive or disabled level. The Y address decoder 504 presents appropriate voltage levels on the column signal lines 505 and 518 to cause the memory cell 501 to be read or written.

The memory cell 501 includes hybrid technology storage device 300 and access circuitry. 502 and 503 which may be NMOS semiconductor devices. The IN terminal 509 of the storage device 300 is connected to ground. The SN terminal at a node 508 is connected to the column line 505 through the source/drain of the NMOS access device 503. The RN terminal at a node 510 is connected to the column line 518 (RL) through the source/drain of the NMOS access device 502. The first word line 506 connects to the gate terminal of NMOS access device 502 and the gate terminal of the NMOS access device 503. When logic state ONE is presented on the first word line 506, a first electrical connection is enabled between the memory cell internal node 508 and the column signal line 505, and a second electrical connection is enabled between the memory cell internal node 510 and the column signal line 518. When logic state ZERO is presented on the word line 506, the first electrical connection and the second electrical connection between the memory cell internal nodes and the column signal lines are disabled.

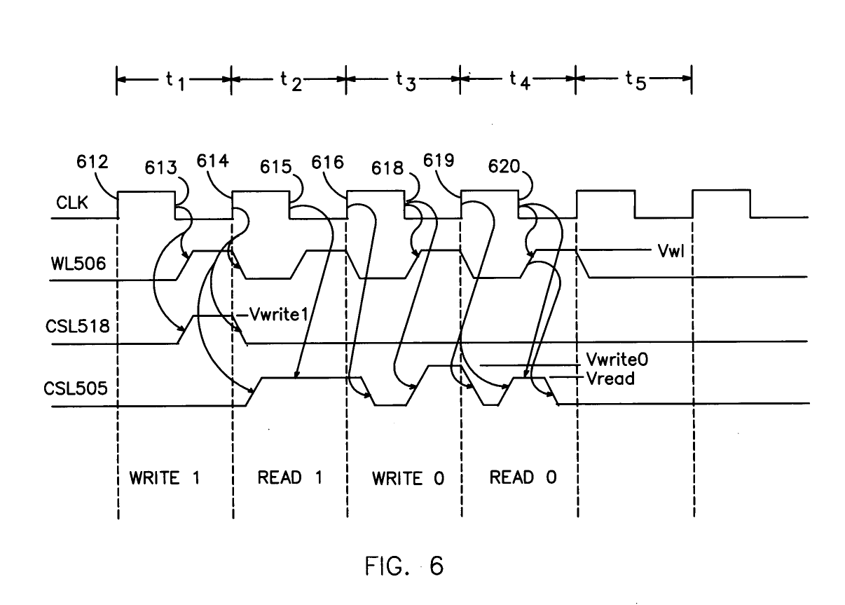

FIG. 6 is a timing diagram illustrating memory array accesses pertaining to the present invention. The periodic clock signal CLK has a period or cycle shown as the time between two consecutive rising edges. In particular, a first clock time period t₁ is the time between a first rising edge 612 and a second consecutive rising edge 614 of the clock signal. The particular embodiment utilizes a single wire periodic clock signal so the clock time period t₁ includes a falling edge 613. Similarly, a second clock time period t₂ is shown as the period between the second rising edge 614 and the third rising edge 616 and includes a second falling edge 615. Subsequent clock cycles are also denoted as t₃, t₄, and t₅.

FIG. 6 illustrates a series of exemplary single cycle access operations on memory cell 501 shown in FIG. 5. First, a logic state ONE is written during a first access operation in cycle t₁. Next, the logic state ONE is read during a second access operation in cycle t₂. Then, a logic state ZERO is written during a third access operation in cycle t₃. Finally, the logic state ZERO written during cycle t₃ is read as a fourth access operation during cycle t₄. A cycle t₅ illustrates an inactive cycle during which no access operation is performed on the memory array.

Although, this example of FIG. 6 illustrates back-to-back single cycle operations, it is also possible to write and read the memory cell 501 following an arbitrary number of “no access” operations. An inactive cycle with no access to memory cell 501 may or may not include an access to the other memory cell 519 of the array 500.

FIG. 6 illustrates the back-to-back accesses to memory cell 501 on first word line 506. As may be seen, during the first clock cycle t₁, the word line 506 goes active in response to the first falling edge 613 of the clock signal and then goes inactive in response to the second rising edge 614.

The triggering relationship between the clock edge 613 and the first rising edge of the word line 506 and the triggering relationship between second rising clock edge 614 and the first falling edge of the word line 506 are clearly illustrated. Subsequent word line accesses triggered during clock cycles t₂, t₃, and t₄ are also illustrated as is the “no access” interval during cycle t₅ on the word line. A voltage level Vw1 for the word line 506 represents an appropriate voltage level for the active state needed to guarantee the successful access of the memory cell 501. Although not shown, it should be understood that at times it may be desirable to use multiple word line voltage levels for the different access operations.

While writing a logic state ONE during clock period t₁, an active logic state on the word line 506 electrically connects the internal node 508 to the column signal line 505 and the internal node 510 to the column signal line 518. The column signal line 505 is held inactive (at logic state ZERO or ground), while the column signal line 518 is driven to the active state (logic state ONE) in response to the trigger provided by the falling clock edge 613. An active state voltage level Vwrite1 on the line 518 is shown as an appropriate write voltage level to guarantee that the logic state ONE is successfully written. Since the voltage between the moveable layer joined to the terminal 509 and the internal node 508 is zero and the bias between the moveable layer and the internal node 510 is Vwrite1, the electrostatic forces maintain the storage switch device 501 in the open condition so that no electrical contact is made between the moveable layer and the node 508. This condition is assumed to denote a logic state ONE, a state which is held indefinitely in this embodiment even though power to the memory array is temporarily removed so long as the memory cell 501 is not re-written to a different state. Consequently, read, no access, and power-off operations may be performed with no loss of data after writing. Although non-volatility is a characteristic of this embodiment of the invention, it should be understood that it is not a requirement. At the end of the write operation and cycle t₁, the word line 506 and the control signal line 505 are returned to their inactive voltage levels.

During clock cycle t₂, the logic state ONE that was previously stored in the memory cell during clock cycle t₁ is read from the memory cell 501. In clock cycle t₂, the word line 506 is driven active as in cycle t₁. In this embodiment, voltage levels for read and write accesses are shown as Vw1 while active; however these levels may be different as a result of design choice in alternate embodiments. Control signal line 518 is held inactive, while control signal line 505 is driven to the read voltage Vread in response to the trigger caused the second rising clock edge 614. The Vread potential is such that it allows a read operation while not allowing a write or accidental disturb. The second falling clock edge 615 triggers the removal of voltage providing hard drive to the control signal line 505 so that the line is no longer driven (or is weakly held) as well as triggering the word line 506 to go active. Since the memory cell 501 is in the open condition storing a logic state ONE, electrically connecting the internal node 508 to the control signal line 505 as a result of activating the word line 506 causes the Vread voltage level on the control signal line 505 to remain unchanged during the remainder of the clock cycle t₂. This situation is interpreted by the Y address decoder and input/output data buffers 504 as a logic state ONE. At the end of the operation and cycle t₂, the word line 506 and the control signal line 505 are returned to their inactive voltage levels.

During clock period t₃, a logic state ZERO is written to the memory cell 501. To accomplish this, an active logic state is provided on the word line 506 to electrically connect the internal node 508 to the column signal line 505 and the internal node 510 to the column signal line 518. The column signal line 518 is held inactive, while the column signal line 505 is driven to the active write state (logic state ONE) in response to the trigger provided by clock edge 618. A voltage level Vwrite0 is illustrated as an appropriate level to guarantee that the write logic state ZERO operation is successful. Since the voltage between the moveable layer connected to terminal 509 and the internal node 510 is zero and the voltage between the moveable layer and the internal node 508 is Vwrite0, the electrostatic forces cause the storage switch device to close so that electrical contact between the layer 509 and the node 508 is made. This state may be taken to denote a logic state ZERO which in this embodiment is held indefinitely, even when power to the memory array is temporarily removed so long as the memory cell 501 is not re-written with a different value. Thus, read, no access, and power off operations may be performed with no loss of data after writing. At the end of the write operation and cycle t₃, the word line 506 and the control signal line 505 are returned to their inactive voltage levels.

It should be noted that in this embodiment the voltage level Vread employed to read the storage device is less than the voltage level Vwrite0 used to write the device, but alternate electromechanical storage devices may be possible with different level requirements (e.g., Vread may less than or equal to Vwrite0). In fact, it should be noted that in the explanations regarding the embodiment, unique voltage levels are utilized for many of the operations; but one skilled in the art may decide that for simplicity similar voltages levels on some of the signals are desirable.

During clock cycle t₄, the logic state ZERO previously stored during clock cycle t₃ is read from memory cell 501. To accomplish this, the word line 506 is driven active as in cycles t₁, t₂, and t₃. Control signal line 518 is held inactive, while control signal line 505 is driven to the read voltage level Vread in response to the trigger provided by the fourth rising clock edge 619. The fourth falling clock edge 620 then triggers the removal of the level driving the control signal line 505 so that the line is no longer driven hard (or floats). The clock edge 620 also triggers the word line 506 going active. Since the memory cell 501 is closed storing a logic state ZERO in which the node 508 is electrically connected to ground, electrically connecting the internal node 508 to the control signal line 505 as a result of the word line 506 going active causes the voltage level Vread on the control signal line 505 to be discharged through the NMOS access device 503 and the storage cell 300. This situation is interpreted by the Y address decoder input/output data buffers 504 as a logic state ZERO. At the end of the operation during cycle t₄, the word line 506 and the control signal line 505 are returned to their inactive voltage levels.

During clock cycle t₅, no access operation is performed. As may be seen, the word line 506, the control signal line 505, and the control signal line 518 are all held at their inactive states so that neither a read nor a write operation is performed on memory cell 501.

Although not discussed in detail, it will be appreciated by those skilled in the art that an erase operation may be accomplished in a manner identical to a write ONE operation since that operation returns a cell to an open condition. Thus, in order to erase a group of cells, all cells of that group are written to a logic ONE state (or a logic ZERO state if a different convention is used).

Understanding the operating characteristics of the memory array of the present invention illustrates various advantages which the array has over memory arrays of the prior art. In addition to providing non-volatile storage and small size, the present invention may significantly increase speed of operation of a memory array. For example, reading the cell described in FIG. 1 of the prior art memory array requires driving both bit lines hard to the voltage of logic level ONE, then removing the hard drive and waiting to detect which of the bit lines falls to logic level ZERO. As pointed out, to speed this operation, sense amplifying circuitry may be added.

Reading the state of the memory cell of the present invention, on the other hand, requires only that a single one of the bit lines be driven to the read voltage, then the hard drive removed and the line sensed to detect the state without the delay of the prior art circuitry. This may significantly increase memory speed and does not demand the extra sensing circuitry of the prior art.

Although the present invention has been described in terms of a preferred embodiment, it will be appreciated that various modifications and alterations might be made by those skilled in the art without departing from the spirit and scope of the invention. The invention should therefore be measured in terms of the claims which follow.

What is claimed is:

1. A memory circuit comprising:
a hybrid electromechanical-semiconductor memory cell,
addressing circuitry connected to the memory cell, and
logic circuitry controlling access to the memory cell allowing single cycle read and write accesses.

2. A memory cell as claimed in claim 1 in which the memory cell includes:
an electromechanical switch having at least a flexible conductive element, and a conductive node; and
semiconductor access circuitry for applying voltages to move the conductive element in and out of contact with the conductive node to define two electrical states, the semiconductor access circuitry providing single cycle access to write and read the electrical state of the switch.

3. A memory circuit as claimed in claim 1 in which the memory cell includes
a nanoscopic element arranged to provide a crossbar switch, and
semiconductor devices controlling access to the crossbar switch.

4. A memory circuit as claimed in claim 1 in which the logic circuitry includes means for applying a pair of signals simultaneously to control the logic state of the memory cell.

5. A memory cell as claimed in claim 3 in which the nanoscopic element is a carbon nanotube element.

6. A memory cell as claimed in claim 1 in which the memory cell includes:
an electromechanical switch having at least a flexible conductive element, and first and second conductive nodes; and
semiconductor access circuitry for applying voltages to move the conductive element in and out of contact with the first conductive node to define two electrical states, the semiconductor access circuitry providing single cycle access to write and read the electrical state of the switch.

7. A memory cell as claimed in claim 6 in which the logic circuitry includes means for applying a pair of signals simultaneously to the first and second conductive nodes to control the logic state of the memory cell.

8. A memory cell comprising:
an electromechanical switch having at least a movable conductive nanoscopic element, and a conductive node; and
semiconductor access circuitry for applying voltages to move the nanoscopic element in and out of contact with the conductive node to define two electrical states, the semiconductor access circuitry providing single cycle access to write and read the electrical state of the switch.

9. A memory cell as claimed in claim 8 in which
the electromechanical switch includes a second node electrically-isolated from the movable conductive nanoscopic element, and
the semiconductor access circuitry provides access to the conductive node and the second node.

10. A memory circuit as claimed in claim 9 in which the logic circuitry includes means for applying a pair of signals simultaneously to control the logic state of the memory cell.

11. A memory cell comprising:
a nanotube switch capable of assuming a conducting state and an open state in response to application of electrical potentials, and
semiconductor switches connected to provide clocked electrical access to the nanotube switch for applying electrical potentials to or sensing electrical potentials at the nanotube switch during any access.

12. A memory cell as claimed in claim 11 in which
the nanotube switch comprises a movable carbon nanotube element connected to a source of potential, and
first and second terminals positioned on opposite sides of the nanotube element and connected to the semiconductor switches.

13. A memory circuit comprising
a plurality of hybrid electromechanical-semiconductor memory cells,
addressing circuitry connected to the memory cells, and
logic circuitry controlling access to the memory cells allowing single cycle read and write accesses to individual memory cells.

14. A memory cell as claimed in claim 13 in which any memory cell includes:
an electromechanical switch having at least a flexible conductive element, and a conductive node; and
semiconductor access circuitry for applying voltages to move the conductive element in and out of contact with the conductive node to define two electrical states, the semiconductor access circuitry providing single cycle access to write and read the electrical state of the switch.

15. A memory cell as claimed in claim 14 in which flexible conductive element is a nanoscopic element.
